(19) United States
(12) Patent Application Publication
(10) Pub. No.: US 2015/0293368 A1
(43) Pub. Date: Oct. 15, 2015

(54) DASHBOARD, AND OPTICAL SYSTEM FOR AUTOMOBILE

(71) Applicant: SHARP KABUSHIKI KAISHA, Osaka (JP)

(72) Inventor: Keiichi Yamamoto, Osaka-shi (JP)

(21) Appl. No.: 14/438,940

(22) PCT Filed: Oct. 10, 2013
(86) PCT No.: PCT/JP2013/077600

§ 371 Date: Apr. 28, 2015

(30) Foreign Application Priority Data
Oct. 29, 2012 (JP) 2012-238034

(51) Int. Cl. G02B 27/22; H05K 7/18

(52) U.S. Cl. CPC G02B 27/2292; H05K 7/186

(57) ABSTRACT

A dashboard (10) in an embodiment according to the present invention is a dashboard for a vehicle. The dashboard (10) includes a reflective type imaging element (20) located in an opening (10v) formed in a top surface of the dashboard; a support member (30) located in an inner space of the dashboard (10), the support member (30) removably supporting a terminal (5) including a display panel (3); and another opening (10u) through which to locate or remove the terminal (5) on or from the support member (30).

### TECHNICAL FIELD

The present invention relates to an dashboard including an optical element capable of forming an image of an object in a space, and a vehicle optical system including such a dashboard.

### BACKGROUND ART

Recently, along with development of mobile information terminals such as smart phones, tablet PCs and the like, smart phones, for example, have increasingly been used as car navigation systems. In the case of being used as a car navigation system, a smart phone is secured inside a vehicle by, for example, an attachment device. Patent Document 1 discloses an attachment device, for a vehicle-mountable image display device, capable of attaching, for example, a vehicle-mountable monitor to a dashboard of the vehicle.

In the meantime, optical systems for forming an image of an object in a space by use of a reflective type imaging element have been proposed (for example, Patent Documents 2 through 4). Such an optical system includes a reflective type imaging element and an object. An image displayed in a space (hereinafter, referred to as an “aerial image”) is an image of the object formed at a position that is plane-symmetric with the object with the reflective type imaging element device, which acts as a plane of symmetry. The optical system utilizes mirror reflection of the reflective type imaging element. In principle, the size ratio of the image of the object and the image formed in a space is 1:1. Patent Documents 2 through 4 are incorporated herein by reference in the entirety thereof.

### CITATION LIST

### Patent Literature

Patent Document 1: Japanese Laid-Open Patent Publication No. 10-281393

Patent Document 2: Japanese Laid-Open Patent Publication No. 2008-158114

Patent Document 3: WO2009/136578

Patent Document 4: WO2007/116639

Patent Document 5: Japanese Laid-Open Patent Publication No. 2011-70074

### SUMMARY OF INVENTION

### Technical Problem

The above-described attachment device for a mobile information terminal is attached to a vehicle by use of, for example, an adhesive sheet. In the case where the attachment device is attached to a dashboard of the vehicle by use of the adhesive sheet, the attachment strength may be insufficient due to oil or any other stain of the dashboard or may be decreased because the adhesive sheet is deteriorated over time by the influence of ultraviolet rays or temperature. If, for example, the vehicle is brought to a sudden stop in such a situation, the mobile information terminal may come off and pup out from the attachment device, or the attachment device itself may be broken. This involves a risk that the mobile information terminal or the attachment device may hit the driver or the passenger.

The present invention made in light of the above-described problem has an object of providing a dashboard capable of decreasing the risk of danger which may be caused to a driver or a passenger by a terminal such as a mobile terminal or the like being attached to the dashboard, and a vehicle optical system including such a dashboard.

### Solution to Problem

A dashboard in an embodiment according to the present invention is a dashboard for a vehicle. The dashboard includes a reflective type imaging element located in an opening formed in a top surface of the dashboard; a support member located in an inner space of the dashboard, the support member removably supporting a terminal including a display panel; and another opening through which to locate or remove the terminal on or from the support member. The support member is located and supports the terminal such that light output from the display panel and reflected by the reflective type imaging element is directly viewable to a viewer.

In an embodiment, the dashboard further includes a lid opening or closing the another opening.

In an embodiment, the dashboard further includes a low reflection layer located on the reflective type imaging element.

A vehicle optical system in an embodiment according to the present invention includes a dashboard according to any one of the above; and the terminal supported by the support member. The vehicle optical system forms an image, corresponding to an image displayed by the display panel, on a side opposite to the side of the terminal with respect to the reflective type imaging element.

In an embodiment, the terminal is connected to an external input device allowing the terminal to be operated with no direct touch on the terminal.

### Advantageous Effects of Invention

Embodiments of the present invention provide a dashboard capable of decreasing the risk of danger which may be caused to a driver or a passenger by a mobile terminal or the like being attached to the dashboard, and a vehicle optical system including such a dashboard.

### BRIEF DESCRIPTION OF DRAWINGS

FIG. 1 is a schematic perspective view of a dashboard 10 in an embodiment according to the present invention.

FIG. 2A is a schematic cross-sectional view of a vehicle optical system 100A in the embodiment according to the present invention.

FIG. 2B is a schematic front view of a support member 30 included in the dashboard 10.

FIG. 3 is a schematic cross-sectional view showing the vehicle optical system 100A.

FIG. 4 is a schematic cross-sectional view of a vehicle optical system 100B in another embodiment according to the present invention.

FIG. 5 is a schematic cross-sectional view of a vehicle optical system 100C in still another embodiment according to the present invention.

FIG. 6 is a schematic cross-sectional view of a vehicle optical system 100D in still another embodiment according to the present invention.

FIG. 7 is a schematic cross-sectional view of a dashboard 10′ in a comparative example that is provided with a support member 30′ on a top surface thereof.

### DESCRIPTION OF EMBODIMENTS

Hereinafter, embodiments according to the present invention will be described with reference to the drawings. The present invention is not limited to the following embodiments.

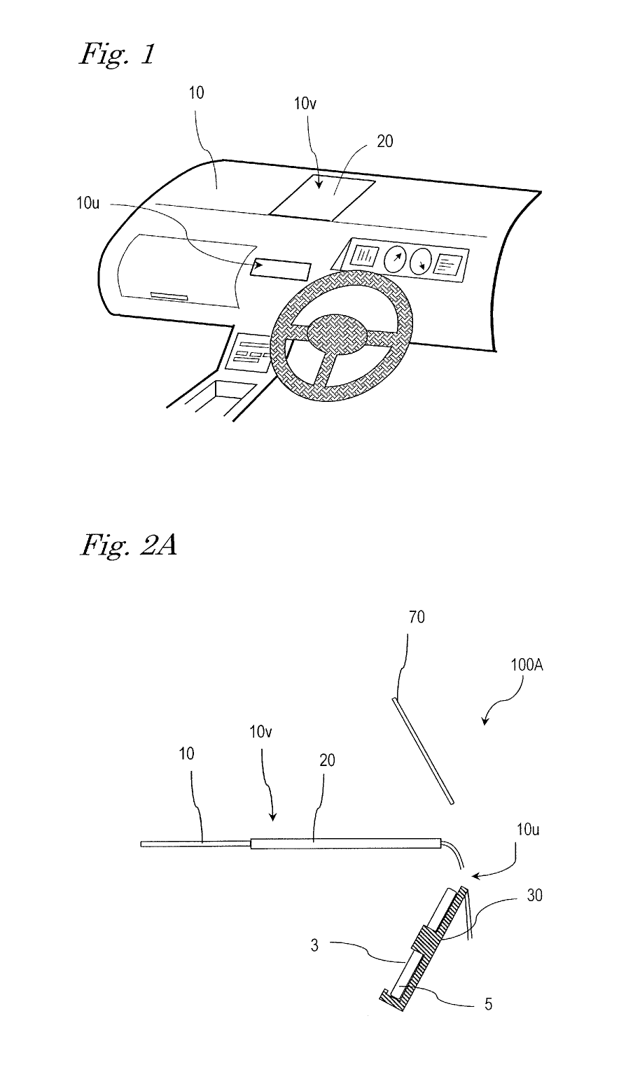

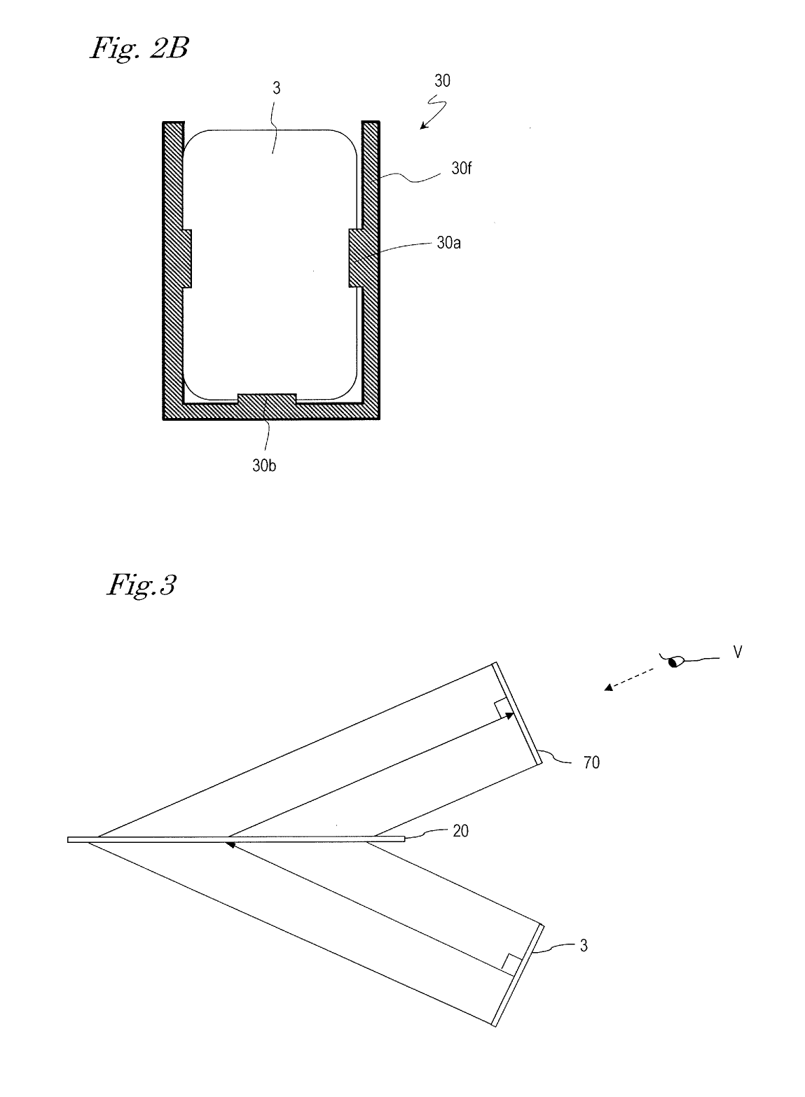

With reference to FIG. 1 through FIG. 3, a dashboard 10 and a vehicle optical system 100A in an embodiment according to the present invention will be described. FIG. 1 is a schematic perspective view of the dashboard 10. FIG. 2A is a schematic cross-sectional view of the vehicle optical system 100A. FIG. 2B is a schematic front view of a support member 30 included in the dashboard 10. FIG. 3 is a schematic cross-sectional view of the vehicle optical system 100A. In FIG. 3, reference sign V refers to a viewer.

The dashboard 10 shown in FIG. 1 is a dashboard for a vehicle. As shown in FIG. 1 and FIG. 2A, the dashboard 10 includes a reflective type imaging element 20 located in an opening 10v formed in a top surface of the dashboard 10, and a support member 30 located in an inner space of the dashboard 10. The support member 30 removably supports a mobile terminal 5 including a display panel 3. The support member 30 supports the mobile terminal 5 such that light output from the display panel 3 and reflected by the reflective type imaging element 20 is directly viewable to the viewer.

In the state of being attached to the support member 30, the mobile terminal 5 is inside the dashboard 10 and cannot be seen from outside the dashboard 10. As described later with reference to FIG. 3, the reflective type imaging element 20 has a function of focusing light from, for example, an object (e.g., display panel 3) on a side opposite to the side of the object with respect to the reflective type imaging element 20. Therefore, an image displayed by the display panel 3 of the mobile terminal 5 located on the support member 30 is reflected by the reflective type imaging element 20 and is visually recognizable by a driver or the like.

As shown in FIG. 2A, the dashboard 10 has another opening 10u through which to locate or remove the mobile terminal 5 on or from the support member 30. The opening 10u, for example, allows the mobile terminal (e.g., smart phone) 5 to be located on the support member 30, so that a function of the mobile terminal 5, for example, a car navigation system is usable. The opening 10u also allows the mobile terminal 5 to be removed from the support member 30. Needless to say, any other function of the mobile terminal 5 (e.g., moving image display function via the Internet) is also usable.

As schematically shown in FIG. 2B, the support member 30 included the dashboard 10 includes a frame 30f and claws 30a and 30b protruding inward from the frame 30f. The claws 30a and 30b are located so as to press a display plane of the display panel 3, and thus prevent the mobile terminal 5 from popping outside.

As shown in FIG. 3, the reflective type imaging element 20 forms an aerial image 70, corresponding to an image displayed by an object (e.g., display panel 3), on a side opposite to the side of the display panel 3 with respect to the reflective type imaging element 20. The aerial image 70 is formed at a position that is plane-symmetric with the display panel 3 with respect to the reflective type imaging element 20, which acts as a plane of symmetry. The display panel 3 is located such that a top end of the display plane thereof is at a bottom position thereof (i.e., such that the image is upside down), whereas the aerial image 70 is displayed such that the top end of the display plane of the display panel 3 is at a top position thereof. The display panel 3 of the mobile terminal 5 and the reflective type imaging element 20 are located such that light reflected by the reflective type imaging element 20 is directly viewable to the viewer V.

As the reflective type imaging element 20, any of reflective type imaging elements disclosed in, for example, Patent Documents 2 through 4 is usable. In the case of having an insufficient mechanical strength, the reflective type imaging element may be sandwiched between transparent plates (e.g., glass plates) when necessary. A transparent plate may be provided only on one surface of the reflective type imaging element. It is preferable that the reflective type imaging element 20 is secured to the dashboard 10 in consideration of safety, ease of visual recognition of the aerial image 70 by the driver, and the like.

The support member 30 is preferably capable of securing the display panel 3 thereto at a predetermined angle. Any known device is usable as the support member 30. The display panel 3 may be secured to the support member 30 at a variable angle.

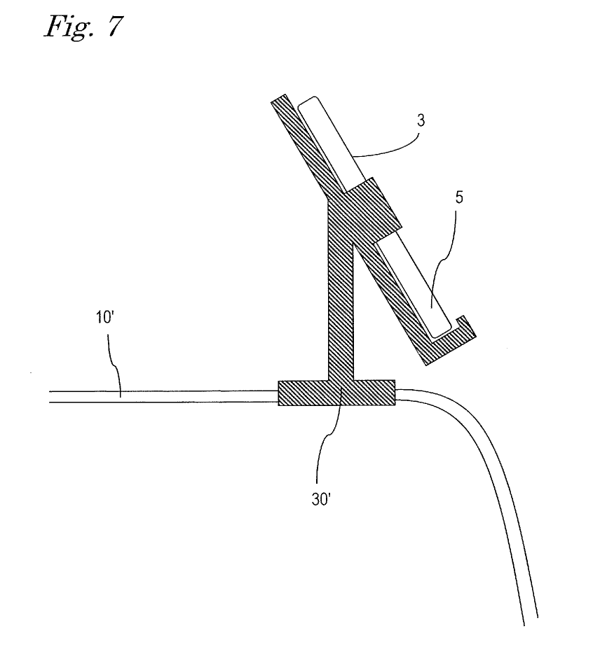

FIG. 7 is a schematic cross-sectional view of a dashboard 10′ in a comparative example. The dashboard 10′ is provided with a support member 30′ on a top surface thereof. The comparative example shown in FIG. 7 involves a risk that when, for example, the vehicle is brought to a sudden stop, the mobile terminal 5 comes off and pops out from the attachment device 30′ or the attachment device 30′ itself is broken, resulting in the mobile terminal 5 or the attachment device 30′ hitting the driver or a passenger. By contrast, in the embodiment according to the present invention, as shown in FIG. 2A, the mobile terminal 5 is located in the inner space of the dashboard 10. Therefore, even when the vehicle is brought to a sudden stop, the possibility that the mobile terminal 5 popping out and hitting the driver or the like is decreased.

In the comparative example shown in FIG. 7, the display panel 3 located above the dashboard 10′ has a relatively long distance from the viewer (e.g., driver). Therefore, an image displayed by the display panel 3 may be difficult to be visually recognized by the driver. By contrast, the aerial image 70 displayed by use of the reflective type imaging element 20 can have a relatively short distance from the viewer (e.g., driver) V, and thus the visual recognizability of the aerial image 70 can be improved. As schematically shown in, for example, FIG. 3, the display panel 30 may be located farther from the reflective type imaging element 20 (further rightward in FIG. 3), so that the aerial image 70 is closer to the viewer V than in FIG. 2A. The arrangement shown in FIG. 3 allows the aerial image 70 to be formed at a position closer to the viewer V. Such an arrangement is easily realized because in general, a front surface of a dashboard protrudes toward the driver from a top surface thereof.

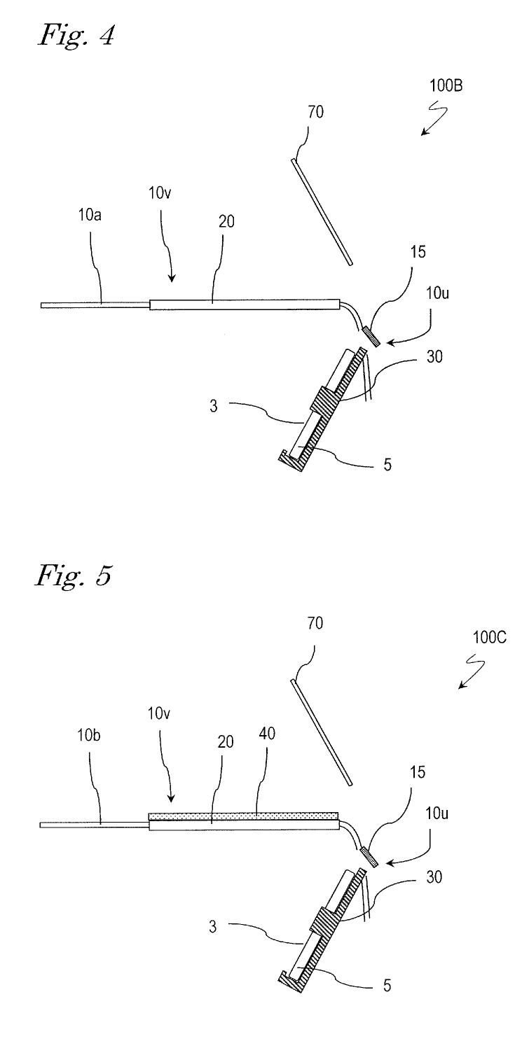

Now, with reference to FIG. 4, a vehicle optical system 100B including a dashboard 10a in another embodiment according to the present invention will be described. FIG. 4 is a schematic cross-sectional view of the optical system 100B including the dashboard 10a. Components common to the optical system 100A will bear the same reference signs thereto, and the same descriptions will not be repeated.

The optical system 100B shown in FIG. 4 includes the dashboard 10a. Unlike the dashboard 10 shown in FIG. 2A, the dashboard 10a includes a lid 15 that opens or closes the opening 10u. The lid 15 thus provided prevents the mobile terminal 5 from popping out from the dashboard 10a in an obliquely upward direction through the opening 10u, and also prevents dust or the like from entering the opening 10u.

Now, with reference to FIG. 5, a vehicle optical system 100C including a dashboard 10b in still another embodiment according to the present invention will be described. FIG. 5 is a schematic cross-sectional view of the optical system 100C including the dashboard 10b. Components common to the optical system 100A will bear the same reference signs thereto, and the same descriptions will not be repeated.

The optical system 100C shown in FIG. 5 includes the dashboard 10b. Unlike the dashboard 10 shown in FIG. 2A, the dashboard 10b includes a low reflection layer 40 (e.g., low reflection film) provided on the reflective type imaging element 20. In the state where the aerial image 70 is displayed, the low reflection layer 40 thus provided prevents the visual recognizability of the aerial image 70 from being decreased by the influence of the sunlight or the like.

In a general vehicle-mountable navigation system, a surface of a display plane of a display panel is treated to have a low reflectance, so that even if the surface is directly exposed to the sunlight, the image is still viewable. By contrast, the display panel 3 of the mobile terminal 5 such as a smart phone or the like is not treated to have a low reflectance. Or, often times, even if the display panel 3 is treated to have a low reflectance, the level of treatment is lower than that for the vehicle-mountable navigation system (the reflectance of the display panel 3 is higher than that of the vehicle-mountable navigation system). Therefore, as shown in, for example, FIG. 7, in the case where the mobile terminal 5 is directly provided on (secured to) the dashboard 10′ in order to use the navigation function of the mobile terminal 5, the image displayed by the display panel 3 may not be viewable when the display plane is directly exposed to the sunlight. The dashboard 10b shown in FIG. 5 includes the low reflection layer 40 provided on the reflective type imaging element 20. Therefore, even if the display plane of the display panel 3 of the mobile terminal 5 is not treated to have a low reflectance, the decrease in the visual recognizability due to the sunlight is suppressed.

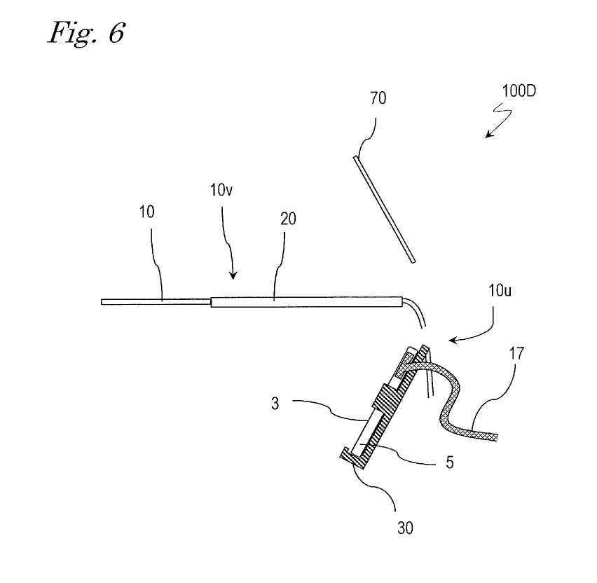

Now, with reference to FIG. 6, a vehicle optical system 100D in still another embodiment according to the present invention will be described. FIG. 6 is a schematic cross-sectional view of the optical system 100D. Components common to the optical system 100A will bear the same reference signs thereto, and the same descriptions will not be repeated.

Unlike in the optical system 100A, in the optical system 100D shown in FIG. 6, the mobile terminal 5 is connected via, for example, an interface cable 17 to an external input device that allows the mobile terminal 5 to be operated with no direct touch on the mobile terminal 5. As described above, the mobile terminal 5 is located in the inner space of the dashboard 10 and thus is not directly operable. In the state where the mobile terminal 5 is connected to the external input device via, for example, the interface cable 17 as described above, the mobile terminal 5 is operable without being directly touched. The mobile terminal 5 may be supplied with a supply voltage (e.g., supply voltage for charge), or a vehicle speed pulse signal or the like, via the interface cable 17. The vehicle speed pulse signal is used for, for example, specifying the position of the vehicle. An audio output of the mobile terminal 5 may be supplied to an audio device of the vehicle via the interface cable 17 or any other cable.

Patent Document 5 discloses a head-up display device located in a dashboard of a vehicle. The display device disclosed in Patent Document 5 also includes a reflective type imaging element. However, the display device disclosed in Patent Document 5 is structured such that an image formed by the reflective type imaging element and reflected by a windshield or the like is viewed by the viewer. The viewer does not directly view the image formed by the reflective type imaging element. This structure has a problem that it is difficult for the viewer to view the image. In addition, the structure disclosed in Patent Document 5 requires the display panel to be located deep inside the dashboard (see, for example, FIG. 2 of Patent Document 5). Therefore, it is difficult for the driver or the like to attach or detach the display panel. In the structure disclosed in Patent Document 5, the image formed by the reflective type imaging element is made upside down when being reflected by the windshield of the like. This requires the image displayed by the display panel in the dashboard to be provided upside down. By contrast, in an embodiment according to the present invention, the image displayed by the display panel (mobile terminal) does not need to be provided upside down, and it is merely required to locate the display panel (mobile terminal) upside down.

This specification discloses a dashboard for a vehicle and a vehicle optical system defined by the following items.

[Item 1]

A dashboard for a vehicle, comprising:

a reflective type imaging element located in an opening formed in a top surface of the dashboard;

a support member located in an inner space of the dashboard, the support member removably supporting a terminal including a display panel; and

another opening through which to locate or remove the terminal on or from the support member;

wherein the support member is located and supports the terminal such that light output from the display panel and reflected by the reflective type imaging element is directly viewable to a viewer.

With the dashboard according to item 1, the terminal is located in the inner space of the dashboard. This can decrease the risk of danger caused to the driver or the passenger. In addition, the driver can locate or remove the terminal on or from the support member through the another opening, and thus can use the car navigation function of the terminal easily.

[Item 2]

The dashboard according to item 1, further comprising a lid opening or closing the another opening.

The dashboard according to item 2 prevents the mobile terminal from popping outside through the another opening. In addition, dust or the like is prevented from entering the another opening.

[Item 3]

The dashboard according to item 1 or 2, further comprising a low reflection layer located on the reflective type imaging element.

The dashboard according to item 3 prevents the visual recognizability of the aerial image 70 from being decreased by the influence of the sunlight or the like.

[Item 4]

A vehicle optical system, comprising:

a dashboard according to any one of items 1 through 3; and

the terminal supported by the support member;
wherein the vehicle optical system forms an image, corresponding to an image displayed by the display panel, on a side opposite to the side of the terminal with respect to the reflective type imaging element.

With the vehicle optical system in item 4, the terminal is located in the inner space of the dashboard. Thus, the risk of danger caused to the driver or the passenger can be decreased.

[Item 5]

The vehicle optical system according to item 4, wherein the terminal is connected to an external input device allowing the terminal to be operated with no direct touch on the terminal.

With the vehicle optical system according to item 5, the terminal can be operated without being directly touched.

### INDUSTRIAL APPLICABILITY

The embodiments of the present invention are widely usable for a dashboard including an optical element capable of forming an image of an object in a space and to a vehicle optical system including such a dashboard.

### REFERENCE SIGNS LIST

3 Display panel
5 Mobile terminal
10 Dashboard
10u, 10v Opening
20 Reflective type imaging element
30 Support member
70 Aerial image
100A, 100B, 100C, 100D Vehicle optical system

1. A dashboard for a vehicle, comprising:
a reflective type imaging element located in an opening formed in a top surface of the dashboard;
a support member located in an inner space of the dashboard, the support member removably supporting a terminal including a display panel; and
another opening through which to locate or remove the terminal on or from the support member;
wherein the support member is located and supports the terminal such that light output from the display panel and reflected by the reflective type imaging element is directly viewable to a viewer.

2. The dashboard according to claim 1, further comprising a lid opening or closing the another opening.

3. The dashboard according to claim 1, further comprising a low reflection layer located on the reflective type imaging element.

4. A vehicle optical system, comprising:
a dashboard according to claim 1; and
the terminal supported by the support member;
wherein the vehicle optical system forms an image, corresponding to an image displayed by the display panel, on a side opposite to the side of the terminal with respect to the reflective type imaging element.

5. The vehicle optical system according to claim 4, wherein the terminal is connected to an external input device allowing the terminal to be operated with no direct touch on the terminal.
